(19) United States
(12) Patent Application Publication
(10) Pub. No.: US 2010/0326720 A1
(43) Pub. Date: Dec. 30, 2010

(54) HOUSING AND PORTABLE ELECTRONIC DEVICE USING THE SAME

(75) Inventors: BEN-DING TSAO, Shindian (TW); WEN-LIN XIONG, Shenzhen City (CN); DIAN-MING ZHU, Shenzhen City (CN); JIANG-YING HU, Shenzhen City (CN); HONG-XI XU, Shenzhen City (CN)

Correspondence Address: Altis Law Group, Inc.;ATTN: Steven Reiss, 288 SOUTH MAYO AVENUE, CITY OF INDUSTRY, CA, 91789, US

(73) Assignees: SHENZHEN FUTAIHONG PRECISION INDUSTRY CO., LTD., ShenZhen City (CN); FIH (HONG KONG) LIMITED, Kowloon (HK)

(21) Appl. No.: 12/757,066

(22) Filed: Apr. 9, 2010

(30) Foreign Application Priority Data
Jun. 25, 2009 (CN) 200910303675.2

(51) Int. Cl. H05K 5/00

(52) U.S. Cl. 174/546

(57) ABSTRACT

A housing comprise a decorative layer including a transparent base, a first conductive coating, an electrically conductive ink layer having a first electrical interface and a second conductive coating having a second electrical interface. The first conductive coating is formed on the base, the electrically conductive ink layer is laminated with and covers the first conductive coating, the second conductive coating is laminated between the electrically conductive ink layer and the outer surface of the substrate, the first electrical interface of the first conductive coating and the second electrical interface of the second conductive coating are electrically connected to a power source for creating an electrical field between the first conductive coating and the second conductive layer to make the electrically conductive ink layer present a pattern.

### BACKGROUND

1. Technical Field

The exemplary disclosure generally relates to housings and portable electronic devices using the housings.

2. Description of Related Art

Currently, portable electronic devices with wireless communication capability, such as mobile phones, are widely used. Consumers can choose to purchase a specific model not only based on performance but also other factors, such as appearance.

Typically, a three-dimensional pattern is formed on the housing by laser holography, to improve the external appearance of the housing. However, the three-dimensional pattern of the housing made by above-mentioned method, cannot meet the requirement of attractive appearance of the housing.

Therefore, there is a room for improvement in the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the exemplary housing and method of manufacturing the housing. Moreover, in the drawings like reference numerals designate corresponding parts throughout the several views. Wherever possible, the same reference numbers are used throughout the drawings to refer to the same or like elements of an embodiment.

FIG. 1 is a schematic view of an exemplary embodiment of a housing including a substrate and a decorative layer.

FIG. 2 is a schematic view of a portable electronic device using the housing of the FIG. 1.

### DETAILED DESCRIPTION OF THE EMBODIMENTS

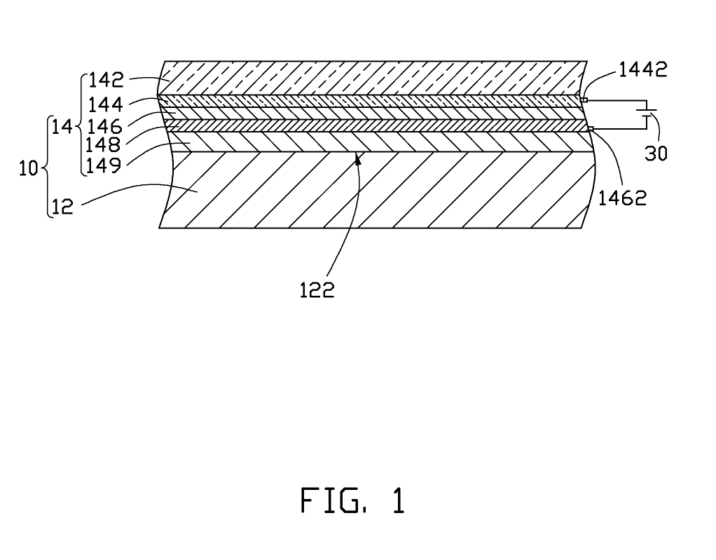

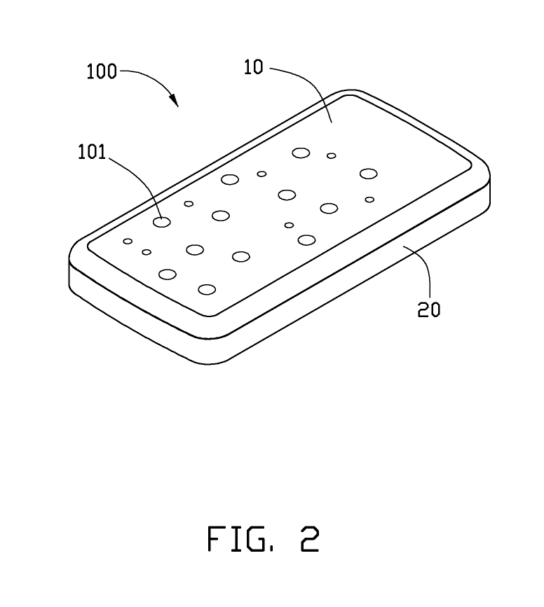

Referring to the FIGS. 1 and 2, an exemplary portable electronic device includes a first housing 10 and a second housing 20 laminated with the first housing 10. The first housing 10 includes a substrate 12 and a decorative layer 14 laminated with the substrate 12 to entirely cover an outer surface 122 of the substrate 12. The decorative layer 14 includes a clear, transparent base 142, a first conductive coating 144, an electrically conductive ink layer 146, a second conductive coating 148, and a protective layer 149. The first conductive coating 144 is formed on one surface of the substrate 142 and covers the mentioned surface of the substrate 142. The electrically conductive ink layer 146 is formed on and covers one surface of the first conductive coating 144 opposite to the substrate 142. The second conductive coating 148 is formed on and covers one surface of the electrically conductive ink layer 146 opposite to first conductive coating 144. The protective layer 149 is formed on and covers one surface of the second conductive coating 148.

The substrate 12 is made of a thermoplastic material such as polyethylene, polycarbonate, acrylonitrile bivinyl styrene, polymethyl methacrylate, or any combination thereof. The substrate 12 is integrally molded on the decorative layer 14 entirely covering one surface of the protective layer 149. It is understood that the substrate 12 may be directly integrally molded with the substrate 142 entirely covering the second conductive coating 148, when the decorative layer 14 does not include the protective layer 149. The substrate 12 also may be hardened to improve the abrasion thereof. The substrate 12 has a thickness of approximately 0.1˜0.2 millimeter.

The material for the substrate 142 may be a resin sheet of a single body or a copolymer of a polypropylene, polyamide, polycarbonate, polymethyl methacrylate or other. The first conductive coating 144 is made of Indium Tin Oxid (ITO) film. The first conductive coating 144 has a thickness of approximately 2˜10 micrometers (μm), and preferably has a thickness of 5 micrometers. The first conductive layer 144 has a first electrical interface 1442 used to electrically connect to a power source 30 of a portable electrical device 100. The electrically conductive ink layer 146 may be produced using ordinary printing methods, such as the gravure printing method, the screen printing method or the offset printing method.

The second conductive layer 148 is made of silver paste or conductive paint. The second conductive layer 148 has a thickness of approximately 8˜10 micrometers (μm). The second conductive layer 148 has a second electrical interface 1482 used to electrically connect to the power source 30. The protective layer 149 is made of an opaque, colored material such as a polyvinyl based resin, a polyamide based resin, a polyester based resin, an acrylic resin, a polyurethane based resin, a polyvinyl acetal based resin, a cellulose ester based resin, or an alkyd resin is preferred as a binder with a colorant containing a pigment or dye of a desired hue. In formation of the protective layer 149, an ordinary ink printing method such as gravure, screen, or offset printing may be used. The protective layer 149 protects the second conductive layer 148 from damage when the decorative layer 14 is integrally molded on the substrate 12.

It is to be understood, when the first electrical interface 1442 of the first conductive coating 144 and the second electrical interface 1482 of the second conductive layer 148 are electrically connected to a power source 30 of the portable electronic device 100, an electrical field between the first conductive coating 144 and the second conductive layer 148 is created, the electrically conductive ink layer 146 then presents a pattern 101 that can be seen from the substrate 142, and the pattern 101 provide an attractive appearance for the first housing 10.

It is to be understood, however, that even though numerous characteristics and advantages of the exemplary disclosure have been set forth in the foregoing description, together with details of the structure and function of the disclosure, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A housing, comprising:
a substrate having an outer surface; and
a decorative layer formed on the outer surface of the substrate, the decorative layer including a transparent base, a first conductive coating, an electrically conductive ink layer having a first electrical interface and a second conductive coating having a second electrical interface;
wherein the first conductive coating is formed on the base, the electrically conductive ink layer is laminated with and covers the first conductive coating, the second conductive coating is laminated between the electrically conductive ink layer and the outer surface of the substrate, the first electrical interface of the first conductive coating and the second electrical interface of the second conductive coating are electrically connected to a power source for creating an electrical field between the first conductive coating and the second conductive layer to make the electrically conductive ink layer present a pattern.

2. The housing as claimed in claim 1, wherein the decorative layer further includes a protective layer laminated between the second conductive coating and the outer surface of the substrate.

3. The housing as claimed in claim 1, wherein the substrate is made of polyethylene, polycarbonate, acrylonitrile bivinyl styrene, or polymethyl methacrylate.

4. The housing as claimed in claim 1, wherein the outer surface is integrally molded on the second conductive layer and entirely covers the entire second conductive layer.

5. The housing as claimed in claim 1, wherein the substrate has a thickness of approximately 0.1˜0.2 millimeter.

6. The housing as claimed in claim 1, wherein the first conductive coating is made of Indium Tin Oxid film.

7. The housing as claimed in claim 6, wherein the first conductive coating has a thickness of approximately 2˜10 micrometers.

8. The housing as claimed in claim 1, wherein the second conductive layer is made of silver paste or conductive paint.

9. The housing as claimed in claim 8, wherein, the second conductive layer has a thickness of approximately 8˜10 micrometers.

10. A portable electronic device, comprising:
a first housing comprising:
a substrate comprising an outer surface; and
a decorative layer formed on the outer surface of the substrate, the decorative layer including a transparent base, a first conductive coating, an electrically conductive ink layer having a first electrical interface and a second conductive coating having a second electrical interface;
wherein the first conductive coating is formed on the base, the electrically conductive ink layer is laminated with and covers the first conductive coating, the second conductive coating is laminated between the electrically conductive ink layer and the outer surface of the substrate, the first electrical interface of the first conductive coating and the second electrical interface of the second conductive coating are electrically connected to a power source for creating an electrical field between the first conductive coating and the second conductive layer to make the electrically conductive ink layer present a pattern.

11. The housing as claimed in claim 10, wherein the decorative layer further includes a protective layer laminated between the second conductive layer and the base outer surface of the base.

12. The housing as claimed in claim 10, wherein the outer surface is integrally molded on the second conductive layer and entirely covers the entire second conductive layer.

13. The housing as claimed in claim 10, wherein the first conductive coating is made of Indium Tin Oxid film.

14. The housing as claimed in claim 10, wherein the second conductive layer is made of silver paste or conductive paint.

15. The housing as claimed in claim 10, wherein the electronic device further includes a power source; the first electrical interface and the second electrical interface are electrically connected the power source.
